(19) United States
(12) Patent Application Publication
(10) Pub. No.: US 2016/0168696 A1
(43) Pub. Date: Jun. 16, 2016

(54) METHOD FOR FORMING A HYDROPHOBIC LAYER

(71) Applicant: INSTITUT POLYTECHNIQUE DE GRENOBLE, Grenoble (FR)

(72) Inventors: Karim Missoum, Grenoble (FR); Julien Bras, Grenoble (FR); Naceur Belgacem, Brie et Angonnes (FR)

(21) Appl. No.: 14/907,326

(22) PCT Filed: Jul. 11, 2014
(86) PCT No.: PCT/FR2014/051797

§ 371 Date: Jan. 25, 2016

(30) Foreign Application Priority Data
Jul. 26, 2013 (FR) 1357375

(51) Int. Cl. C23C 16/44; C09D 101/02

(52) U.S. Cl. CPC C23C 16/44; C09D 101/02

(57) ABSTRACT

The invention relates to a method for forming a film-forming hydrophobic layer on a substrate, which method includes: fanning an aqueous suspension of cellulose nanofibers, CNF; forming, in water and with a water-immiscible solvent having an evaporation temperature below that of water, a cationic nanoemulsion of a substance forming covalent bonds with the cellulose; mixing the suspension and the nanoemulsion such as to produce a mixture resulting from an adsorption of said substance by the CNF; coating a substrate with said mixture; and proceeding to an annealing suitable for grafting said substance to the CNF.

### CROSS-REFERENCES TO RELATED APPLICATIONS

This application claims the benefit of International Application No. PCT/FR2014/051797, filed Jul. 11, 2014, which claims the priority benefit of French patent application FR13/57375, filed on Jul. 26, 2013 and incorporates the disclosures of each application by reference.

### BACKGROUND

The present invention relates to a method of forming a hydrophobic layer on a substrate.

### DISCUSSION OF THE RELATED ART

Generally, it is often desired to form on a substrate a strongly hydrophobic layer to limit its interaction with water (for example, in textile, windshields). More particularly, it may be desired to form such a layer on paper to give it hydrophobic properties, paper being naturally hydrophilic.

To achieve this result, one may either chemically modify the surface, or use a coating slip. Examples of currently-used coating slips are mixtures of binders such as latex (acrylic or styrene-butadiene) or water soluble polymers (starch, CMC, PVA, casein) and pigmentary fillers which may be mineral (ground or precipitated calcium carbonate, kaolin, talcum, TiO₂) or organic. Certain additives such as dispersants, optical brighteners, antifoams, insolubilizers, lubricants, etc. may also be added. In the case of coating slips, fluorinated polymers are also used. In all cases, such slips are non-transparent and do not have a biologic origin, which limits their applications.

It is also known, to protect, seal, or color paper substrates, to coat them with a layer of cellulose microfibers, MFC, or microfibrillated cellulose, with only one added filler.

However, the various previously described hydrophobic layer forming and deposition methods have the disadvantages of being relatively complex and/or to have non-optimal hydrophoby characteristics.

### SUMMARY

It is here desired to simplify and to improve the hydrophoby characteristics of a hydrophobic protection layer.

According to an embodiment of the present invention a method of forming a film-forming hydrophobic layer on a substrate is provided, comprising:

forming an aqueous suspension of cellulose nanofibers, CNFs;

forming, in water with a water-immiscible solvent having an evaporation temperature lower than that of water, a cationic nanoemulsion of a substance capable of forming covalent bonds with the cellulose;

mixing the suspension and the nanoemulsion to form a mixture resulting from an adsorption of said substance by the CNFs;

coating a substrate with said mixture; and

performing an anneal capable of grafting said substance on the CNFs.

According to an embodiment, said substance is selected from the group comprising AKD, ASA, acyl chloride, fatty isocyanate, fatty carboxylic acid, thiocyanate, and fatty anhydride, and said solvent is selected from the group comprising: chloroform, DMF, dichloromethane, pentane, hexane, ethyl ether.

According to an embodiment, said substance is AKD and said solvent is chloroform.

According to an embodiment, the nanoemulsion contains a surfactant.

According to an embodiment, the CNFs have a diameter in a range from 10 to 200 nm and the micelles of the nanoemulsion have dimensions of the same order of magnitude as said diameter.

According to an embodiment, the substrate is paper, cardboard, glass, a textile, a plastic material.

### BRIEF DESCRIPTION OF THE DRAWINGS

The foregoing and other features and advantages will be discussed in detail in the following non-limiting description of specific embodiments in connection with the accompanying drawings, among which:

FIG. 1 illustrates successive steps of the manufacturing of an AKD nanoemulsion;

FIG. 2A illustrates successive steps of the forming of a CNF-AKD solution; and

FIG. 2B shows the aspect of the products obtained in the various solutions discussed in FIG. 2A;

FIG. 3 illustrates successive steps of coating a substrate with a hydrophobic CNF-AKD layer; and

FIG. 4 shows a hydrophobic layer coating a substrate.

### DETAILED DESCRIPTION

Generally, it is here provided to form a film-forming hydrophobic layer by mixing a nanoemulsion of an alkyl ketene dimer, currently called AKD, with cellulose nanofibers.

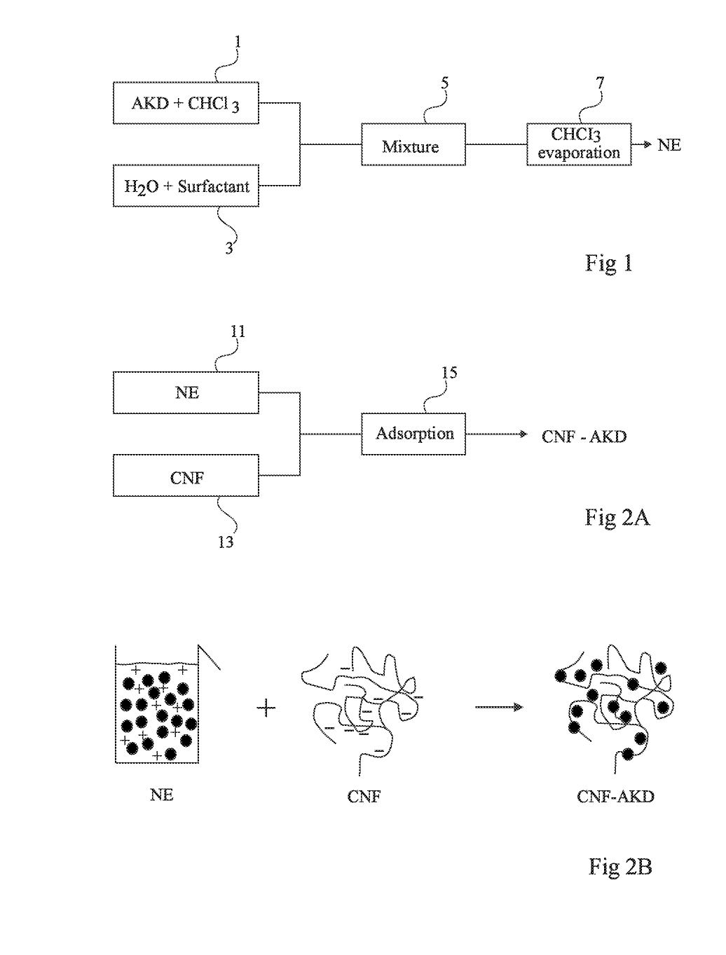

FIG. 1 shows steps of the forming of the AKD nanoemulsion. One uses as an initial material, on the one hand, a solution of AKD in chloroform, CHCl₃, (block 1) and on the other hand, a cationic surfactant dissolved in water (block 3). The surfactant is for example tetradecyl trimethyl ammonium bromide (TTAB). The two solutions are mixed (block 5) with an ultrasound stirring, for example, for a plurality of minutes. It is here desired to obtain micelles having a diameter in the range from 50 to 400 nm, and experience shows that they may be obtained with a good reproducibility and a low dimension distribution (under 10%). After this (block 7), a heating at a temperature in the range from 40 to 90° C., for example 70° C., is performed to evaporate the chloroform. A nanoemulsion, NE, of micelles of AKD linked to surfactant is thus obtained, the micelles being positively charged.

Then, as illustrated in FIG. 2, the nanoemulsion, NE, (block 11) obtained after the steps described in the example of FIG. 1 in suspension in water is mixed (block 13) with an aqueous suspension of cellulose nanofibers, CNFs. The cellulose nanofibers have a diameter smaller than one micrometer, preferably in the range from 5 to 200 nm, preferably from 10 to 60 nm. The cellulose nanofibers are obtained by any known method, from wood pulp, for example, spruce and pine pulp. Their surface state is preferably modified by using, for example, fibers said to be TEMPO-oxidized, that is, oxidized in the presence of 2,2,6,6-tetramethyl piperidine 1-oxyl or by using an enzyme treatment. The proportion of nanofibers in water is for example in the range from 1 to 5% by weight. The mixture (block 15) of nanofibers and AKD, CNF-AKD, is performed at low temperature (lower than 40° C.), to only obtain a phenomenon of adsorption of the AKD micelles by the cellulose nanofibers. The temperature is maintained sufficiently low during the mixing so that no grafting occurs (so that the micelle does not coalesce on the fiber). Thus, the link between the micelles and the nanofibers is purely electrostatic.

FIG. 2B very schematically shows the aspect (i) of the nanoemulsion, NE, one or a plurality of positive charges being linked to each micelle, (ii) of a group of cellulose nanofibers, CNF, having each of its fibers supporting a set of negative charges, and (iii) of the adsorbed structure, CNF-AKD, where nanoemulsion micelles shown with black dots are electrostatically linked to cellulose nanofibers.

An advantage of the CNF-AKD mixture obtained by adsorption is that it is extremely stable over time. It may remain unaffected for a duration of from one to a plurality of weeks. Further, the concentration of the mixture in water may be relatively high, from 5 to 10% by weight, while keeping a relatively low viscosity (for example, 0.155 Pa·s for a 5% concentration of CNF-AKD for a 100 s⁻¹ shearing speed).

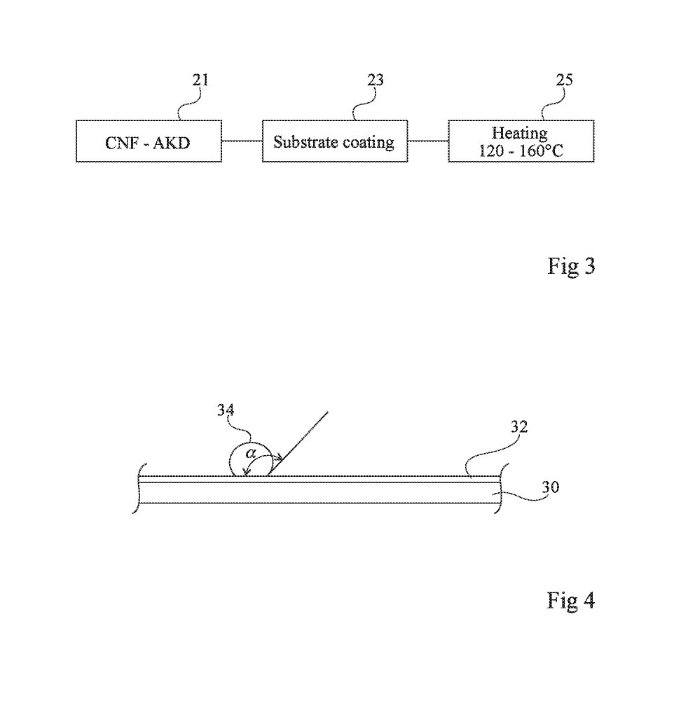

As illustrated in FIG. 3, the CNF-AKD mixture (block 21) may be directly used to directly coat a substrate (block 23), the coated surfaces thereof being desired to be made hydrophobic. Conversely to the other solutions of chemical modifications of CNFs to make them hydrophobic, this hydrophobic layer has good film-forming qualities, that is, it deposits in a regular layer and does not divide into micro “lumps” or clusters. Indeed, up to now, any chemical modification performed to make CNFs hydrophobic would not allow the conservation of film-forming properties: a powder was obtained.

Then only (block 25), once the CNF-AKD layer has been deposited by any conventional method, for example, by bar coating, an anneal at a temperature in the range from 110 to 150° C. is carried out so that the electrostatic link between the AKD micelles and the CNFs transforms into a chemical grafting—a covalent bond. The layer is then definitively stabilized.

An advantage of this process is that an extremely thin film may be deposited, having a thickness in the range from 0.2 to 5 μm, this thickness being kept after grafting.

Another advantage of this process is that it is not necessary to provide adding products generally present in a coating slip, such as discussed at the beginning of the present description.

FIG. 4 shows a substrate 30, for example, a glass slide or a paper sheet coated with a layer 32 obtained by the method described in relation with FIGS. 1 to 3. On layer 32, a water drop 34 having its edges forming with the surface of layer 32 an obtuse angle α, characteristic of a hydrophobic coating, has been shown. This angle may for example be in the range from 90 to 140°.

A specific embodiment of the present invention has been previously described. Various alterations and modifications will occur to those skilled in the art. In particular, to form the nanoemulsion, instead of starting from AKD dissolved in chloroform, any polarized substance capable of forming covalent bonds with cellulose to graft thereon may be used. This substance may be selected from the group comprising AKD, ASA, acyl chloride, fatty isocyanate, fatty carboxylic acid, thiocyanate, and fatty anhydride. Similarly, this substance may be dissolved in other solvents than chloroform. Whether this solvent is non-miscible in water and has an evaporation temperature lower than that of water matters little. A solvent may for example be selected from the group comprising: chloroform, DMF, dichloromethane, pentane, hexane, ethyl ether.

1. A method of forming a film-forming hydrophobic layer on a substrate, comprising:
forming an aqueous suspension of cellulose nanofibers, CNFs;
forming, in water with a water-immiscible solvent having an evaporation temperature lower than that of water, a cationic nanoemulsion of a substance capable of forming covalent bonds with cellulose;
mixing the suspension and the nanoemulsion to form a mixture resulting from an adsorption of said substance by the CNFs;
coating a substrate with said mixture; and
performing an anneal capable of grafting said substance on the CNFs.

2. The method of claim 1, wherein:
said substance is selected from the group comprising AKD, ASA, acyl chloride, fatty isocyanate, fatty carboxylic acid, thiocyanate, and fatty anhydride, and
said solvent is selected from the group comprising: chloroform, DMF, dichloromethane, pentane, hexane, ethyl ether.

3. The method of claim 2, wherein said substance is AKD and said solvent is chloroform.

4. The method of claim 1, wherein the nanoemulsion contains a surfactant.

5. The method of claim 1, wherein the CNFs have a diameter in a range from 10 to 200 nm and the micelles of the nanoemulsion have dimensions of the same order of magnitude as said diameter.

6. The method of claim 1, wherein the substrate is paper, cardboard, glass, a textile, a plastic material.
